(19) United States
(12) Patent Application Publication
(10) Pub. No.: US 2014/0210021 A1
(43) Pub. Date: Jul. 31, 2014

(54) METHOD AND APPARATUS FOR AMELIORATING PERIPHERAL EDGE DAMAGE IN MAGNETORESISTIVE TUNNEL JUNCTION (MTJ) DEVICE FERROMAGNETIC LAYERS

(71) Applicant: QUALCOMM INCORPORATED, San Diego, CA (US)

(72) Inventors: Xiaochun Zhu, San Diego, CA (US); Xia Li, San Diego, CA (US); Seung H. Kang, San Diego, CA (US)

(73) Assignee: QUALCOMM INCORPORATED, San Diego, CA (US)

(21) Appl. No.: 13/749,731

(22) Filed: Jan. 25, 2013

(51) Int. Cl. H01L 43/12; H01L 43/02

(52) U.S. Cl. CPC H01L 43/12; H01L 43/02
USPC 257/421; 156/345.1; 438/3

(57) ABSTRACT

An in-process magnetic layer having an in-process area dimension is formed with a chemically damaged region at a periphery. At least a portion of the chemically damaged region is transformed to a chemically modified peripheral portion that is non-ferromagnetic. Optionally, the transforming is by oxidation, nitridation or fluorination, or combinations of the same.

### FIELD OF DISCLOSURE

The technical field of the disclosure relates to fabrication and structure of magneto-resistive elements in magnetic tunnel junction (MTJ) memory cells.

### BACKGROUND

MTJ is considered a promising technology for next generation non-volatile memory. Potential benefits include fast switching, high switching cycle endurance, low power consumption, and extended unpowered archival storage.

One conventional MTJ element has a fixed magnetization layer (alternatively termed “pinned” or “reference” layer), and a “free” magnetization layer, separated by a tunnel barrier layer. The free layer is switchable between two opposite magnetization states, with one being “parallel” (P) to the magnetization of the fixed layer, and the other being opposite, or anti-parallel” (AP), to the fixed magnetic layer. The MTJ element is termed “magneto-resistive” because when in the P state its electrical resistance is lower than when in the AP state. By injecting a write current, the magnetization of the MTJ free layer can be switched between the P and AP states. The direction of the write current is determinative of the state. The P and AP states can correspond to a “0” and a “1,” i.e., one binary bit, by injecting a reference current and detecting the voltage.

Materials and structure of the fixed layer and free layer are directed to impart these layers with certain ferromagnetic properties. Known techniques of fabricating MTJ elements include etching a large area multilayer structure, having the constituent layers for what will become an array of MTJ elements, leaving an array of elliptical pillars, each being a stack of the constituent layers of the starting large area multilayer structure. Because of the staking order of the constituent layers, their respective thicknesses, and respective electrical, ferromagnetic, and/or insulating properties, each pillar is an MTJ element.

However, certain of the etching processes can result in chemical damage at the peripheral of ferromagnetic layers of the pillars. The chemically damaged peripheral of these ferromagnetic layers may retain, and may exhibit certain ferromagnetic properties. However, the values of one or more of the parameters characterizing the ferromagnetism of the damaged peripheral may differ, significantly, from their starting values. Various costs may be attributable to the damage. Examples may include reduced device yield, and reduced MTJ device density.

### SUMMARY

In one embodiment, methods are provided for forming a magnetic tunnel junction layer, and examples may include forming an in-process ferromagnetic layer having a ferromagnetic main region surrounded by a chemically damaged peripheral region, such that the chemically damaged peripheral region is weak ferromagnetic, in combination with transforming at least a portion of the chemically damaged peripheral region to a chemically modified peripheral portion that is non-ferromagnetic.

In an aspect, transforming at least a portion of the chemically damaged region to the chemically modified peripheral portion may comprise oxidation, nitriding, or fluorination, or may comprise any combination of oxidation, nitriding, and/or fluorination.

In an aspect of one embodiment, methods may further include forming a protective layer to surround the chemically modified peripheral portion.

In an another aspect of one embodiment, methods may include identifying or providing a target effective area for the magnetic tunnel junction layer, and performing the forming of the in-process ferromagnetic layer to provide the in-process ferromagnetic layer with an area dimension larger than the target effective area. In a related aspect, the transforming may form the magnetic tunnel junction layer with a ferromagnetic main region having an area approximately equal to the target effective area.

In one embodiment, methods are provided for fabricating a magnetic tunnel junction device, and examples may include providing a multi-layer structure including a substrate, a pinned ferromagnetic layer above the substrate, a tunnel barrier layer above the pinned ferromagnetic layer, and a ferromagnetic free layer above the tunnel barrier layer. In an aspect, methods include etching the multi-layer structure to form a pillar, the pillar including an in-process ferromagnetic layer having a portion of the ferromagnetic free layer. In a related aspect, the etching may form the in-process ferromagnetic layer to include a ferromagnetic main region and a chemically damaged peripheral region surrounding the ferromagnetic main region, wherein the chemically damaged peripheral region is weak ferromagnetic. Methods according to the one embodiment further include transforming at least a portion of the chemically damaged peripheral region to a chemically modified peripheral portion and, according to an aspect; the chemically modified peripheral portion is ferromagnetic dead.

In an aspect, methods may further include forming a protective layer to surround the chemically modified peripheral portion, and another etching to further form the pillar to include another in-process ferromagnetic layer, the another in-process ferromagnetic layer having a portion of the pinned ferromagnetic layer.

In one embodiment, methods are provided for forming a magnetic tunnel junction (MTJ) layer, and may include step of forming an in-process magnetic layer having an in-process area dimension larger than a target effective MTJ area, wherein the forming forms a chemically damaged region at a periphery of the in-process magnetic layer, in combination with step of transforming at least a portion of the chemically damaged region to a chemically modified peripheral portion, wherein the chemically modified peripheral portion is non-ferromagnetic.

One embodiment provides an apparatus for forming a magnetic tunnel junction (MTJ) layer, and example apparatuses may include means for forming an in-process ferromagnetic layer having an in-process area dimension larger than a target MTJ area, wherein the forming forms a chemically damaged region at a periphery of the in-process magnetic layer, and means for transforming at least a portion of the chemically damaged region to a chemically modified peripheral portion, wherein the chemically modified peripheral portion is ferromagnetic dead.

In an aspect, example apparatuses may further include means for protecting the chemically modified peripheral portion against damage from further processing.

One embodiment provides an apparatus for fabricating a magnetic tunnel junction (MTJ) device and example apparatuses may include means for forming a pillar including an in-process magnetic layer having an in-process area dimension larger than the given area dimension, wherein the forming forms a chemically damaged region at a periphery of the in-process magnetic layer, and means for transforming at least a portion of the chemically damaged region to a chemically modified peripheral portion, wherein the chemically modified peripheral portion is ferromagnetic dead.

One embodiment provides a magnetic tunnel junction device that may include a substrate, a pinned ferromagnetic layer above the substrate, a tunnel barrier layer above the pinned ferromagnetic layer, and a ferromagnetic free layer above the tunnel barrier layer, and at least one of the pinned ferromagnetic layer or the ferromagnetic free layer may have a ferromagnetic main region surrounded by a peripheral edge region that is ferromagnetic dead.

One embodiment provides a computer-readable medium comprising instructions, which, when executed by a processor apparatus, cause the processor apparatus to perform operations carrying out a method for forming a magnetic tunnel junction layer, comprising instructions that may cause the processor apparatus to form an in-process ferromagnetic layer having a ferromagnetic main region surrounded by a chemically damaged peripheral edge region that is weak ferromagnetic. The one embodiment further includes instructions that, when executed by a processor, cause the processor to transform at least a portion of the chemically damaged peripheral edge region to a chemically modified peripheral portion to form the magnetic tunnel junction layer and, in an aspect, the chemically modified peripheral portion is non-ferromagnetic.

One embodiment provides a computer-readable medium comprising instructions, which, when executed by a processor apparatus, cause the processor apparatus to perform operations carrying out a method for fabricating a magnetic tunnel junction device comprising instructions that may cause the processor apparatus to etch a multi-layer structure having a substrate, a pinned ferromagnetic layer above the substrate, a tunnel barrier layer above the pinned ferromagnetic layer, and a ferromagnetic free layer above the tunnel barrier layer, to form a pillar, wherein the pillar includes an in-process ferromagnetic layer having a portion of the ferromagnetic free layer, wherein the in-process ferromagnetic layer includes a ferromagnetic main region and a chemically damaged peripheral region surrounding the ferromagnetic main region, wherein the chemically damaged peripheral region is weak ferromagnetic, and wherein the instructions further comprise instructions that cause the processor apparatus to transform at least a portion of the chemically damaged peripheral region to a chemically modified peripheral portion, wherein the chemically modified peripheral portion is ferromagnetic dead.

### BRIEF DESCRIPTION OF THE DRAWINGS

The accompanying drawings found in the attachments are presented to aid in the description of embodiments of the invention and are provided solely for illustration of the embodiments and not limitation thereof.

FIG. 1 is a cross-sectional view, on a projection plane normal to the extending plane of constituent layers, of one conventional multi-layer pillar structure of one example conventional multi-layer MTJ device.

FIG. 2 is a view from the FIG. 1 projection 2-2, of one ferromagnetic layer of the FIG. 1 conventional multi-layer MTJ device, with a superposed diagram indicating a peripheral region having “ideal” chemical/ferromagnetic structure.

FIG. 3A is the FIG. 1 cross-sectional view of one conventional multi-layer pillar structure of one conventional multi-layer MTJ device, with a superposed diagram showing exemplary spatial aspects of damaged peripheral regions of MTJ ferromagnetic layers formed in conventional etching.

FIG. 3B shows, by superposed diagram on the FIG. 3A projection plane 3-3, exemplary spatial aspects of conventional etching damaged peripheral regions of one of the example MTJ ferromagnetic layers of the FIG. 3A conventional multi-layer MTJ device.

FIG. 4A is a cross-sectional view, on a projection plane normal to the extending plane of constituent layers, showing aspects of one example chemically modified edge multi-layer MTJ device structured according to, and formed in accordance with one exemplary embodiment.

FIG. 4B is a view from FIG. 4A projection 4-4, showing one chemically modified edge ferromagnetic layer of the FIG. 4A chemically modified edge multi-layer MTJ device structured according to, and formed in accordance with one exemplary embodiment.

FIG. 5A is a cross-sectional view, on a projection plane normal to the extending plane of constituent layers, showing aspects of one example chemically modified edge multi-layer MTJ device structured according to, and formed in accordance with another exemplary embodiment.

FIG. 5B is a view from FIG. 5A projection 5-5, showing one chemically modified edge ferromagnetic layer of the FIG. 5A chemically modified edge multi-layer MTJ device structured according to, and formed in accordance with the another exemplary embodiment.

FIGS. 6A-6F show a snapshot sequence of cross-sectional diagrams, on a projection plane normal to the extending plane of constituent starting and in-progress layers, describing example structures and example processes providing one chemically modified edge multi-layer MTJ device in accordance with one or more exemplary embodiments.

FIGS. 7A-7F show a snapshot sequence of cross-sectional diagrams, on a projection plane normal to the extending plane of constituent starting and in-progress layers, describing example structures and example processes providing one chemically modified edge multi-layer MTJ device in accordance with another one or more exemplary embodiments.

FIG. 8 shows one flow chart diagram of operations further to various aspects providing chemically modified edge multi-layer MTJ devices according to one or more exemplary embodiments.

FIG. 9 shows one system diagram of one wireless communication system having, supporting, integrating and/or employing chemically modified edge multi-layer MTJ devices, and processes of fabricating chemically modified edge multi-layer MTJ devices, according to aspects of various exemplary embodiments.

### DETAILED DESCRIPTION

Aspects of the invention are disclosed in the following description and related drawings directed to specific embodiments of the invention. Alternate embodiments may be devised without departing from the scope of the invention. Additionally, well-known elements of the invention will not be described in detail or will be omitted so as not to obscure the relevant details of the invention.

The word “exemplary” is used herein to mean “serving as an example, instance, or illustration.” Any embodiment described herein as “exemplary” is not necessarily to be construed as preferred or advantageous over other embodiments. Likewise, the term “embodiments of the invention” does not require that all embodiments of the invention include the discussed feature, advantage or mode of operation.

The terminology used herein is for the purpose of describing examples according to particular embodiments and is not intended to be limiting of embodiments of the invention. As used herein, the singular forms “a”. “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

Further, many embodiments are described in terms of sequences of actions to be performed by, for example, elements of a computing device. It will be recognized that various actions described herein can be performed by specific circuits (e.g., application specific integrated circuits (ASICs)), by program instructions being executed by one or more processors, or by a combination of both. Additionally, these sequence of actions described herein can be considered to be embodied entirely within any form of computer readable storage medium having stored therein a corresponding set of computer instructions that, upon execution, would cause an associated processor to perform the functionality described herein. Thus, the various aspects of the invention may be embodied in a number of different forms, all of which have been contemplated to be within the scope of the claimed subject matter. In addition, for each of the embodiments described herein, illustrative implementations and forms may be described as, for example, “logic configured to” perform the described action.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields, electron spins particles, electrospins, or any combination thereof.

Further, those of skill in the art will appreciate that the various illustrative logical blocks, modules, circuits, and algorithm steps described in connection with the embodiments disclosed herein may be implemented as electronic hardware, computer software, or combinations of both. Interchangeability of hardware and software for various illustrative components, blocks, modules, circuits, and steps is shown by describing these generally in terms of their functionality. As will be readily appreciated by persons of ordinary skill in the art from reading this disclosure, whether such functionality is implemented as hardware or software, or a combination of hardware and software, depends upon the particular application and design constraints imposed on the overall system. Skilled artisans may implement the described functionality in varying ways for each particular application, but such implementation decisions should not be interpreted as causing a departure from the scope of the present invention.

FIG. 1 shows a cross-sectional view of a multi-layer magnetic tunnel junction device 100 (hereinafter “multi-layer MTJ device” 100) formed in a conventional fabrication of MTJ devices. The FIG. 1 multi-layer MTJ device 100 is shown in simplified form omitting, for example, read/write access and other circuitry for which description is not necessary for persons of ordinary skill in the art, having view of this disclosure, to understand the inventive concepts and practice according to one or more of the exemplary embodiments. It will be understood that “device,” as used in the term “multi-layer MTJ device” 100 is not limited to a fully fabricated device. For example, the multi-layer MTJ device 100 can be an “in-process” structure, i.e., portions (not separately labeled) of its depicted structure may be removed or may be modified by subsequent processing, in accordance with conventional MTJ fabrication techniques.

Referring to FIG. 1, the multi-layer MTJ device 100 can include multi-layer structure termed in this disclosure as an “MTJ pillar” 102. The MTJ pillar 102 may be arranged on a conventional MTJ substrate 104 (hereinafter referenced as “substrate 104”). The MTJ pillar 102 comprises stacked layers, for example, bottom electrode 106, seed layer 108, anti-ferromagnetic (AF) pinning layer 110, ferromagnetic pinned layer 112, tunnel barrier layer 114, ferromagnetic free layer 116 and capping layer 118. Each of the described layers is shown oriented, relative to the X-Z projection plane of FIG. 1, as extending in the X-Y plane, with X being the horizontal axis and Y being normal to the X-Z projection plane, with each having a respective thickness (shown by not separately labeled) in the Z direction.

Referring still to FIG. 1, materials, dimensions (e.g., thickness), functions, and mechanisms of operation of each of the bottom electrode 106, seed layer 108, AF pinning layer 110, ferromagnetic pinned layer 112, tunnel barrier layer 114, ferromagnetic free layer 116 and capping layer 118 can be according to conventional techniques. Therefore, except where incidental to later description of example aspects and operations according to exemplary embodiments, further detailed description is omitted.

As will be appreciated by persons of ordinary skill in the art, the FIG. 1 arrangement of the bottom electrode 106, seed layer 108, AF pinning layer 110, ferromagnetic pinned layer 112, tunnel barrier layer 114, ferromagnetic free layer 116 and capping layer 118, FIG. 1 MTJ pillar 102 can exemplify structural aspects found in various conventional MTJ devices (not shown in the figures). It will also be understood by such persons that conventional MTJ devices having structural features as shown in FIG. 1 can include additional layers, for example, additional metal oxide layers between depicted layers. Conventional MTJ devices can also form certain of the depicted layers, e.g., the ferromagnetic free layer 116, as multi-layer structures.

Referring still to FIG. 1, it will also be understood by such persons that conventional fabrication techniques for multi-layer MTJ devices identical to, or comparable to the MTJ pillar 102 may start by forming, on a substrate such as the example substrate 104, a larger (in terms of extension in the X-Y plane) multi-layer MTJ structure (not explicitly shown) having the FIG. 1 cross section of layers. The larger multi-layer structure can be referred to as an “MTJ multi-layer starting structure.” The MTJ multi-layer starting structure may extend, for example, in the X and Y directions a distance substantially larger than DM1 and DM2, respectively, of the FIG. 1 example MTJ pillar 102. Conventional MTJ fabrication techniques can then remove material from the MTJ multi-layer starting structure, for example by one or more etching processes, to obtain the MTJ pillar 102 as a remaining structure. Known conventional fabrication equipment and systems can be employed and, therefore, except where incidental to later description of example aspects and operations according to exemplary embodiments, further detailed description is omitted.

Before describing certain characteristics of known conventional MTJ fabrication techniques that illustrate, relate to, can be an environment, and/or can be modified in accordance with exemplary embodiments, certain ideal structural aspects of layers such as the ferromagnetic free layer 116 of the MTJ pillar 102 will be discussed.

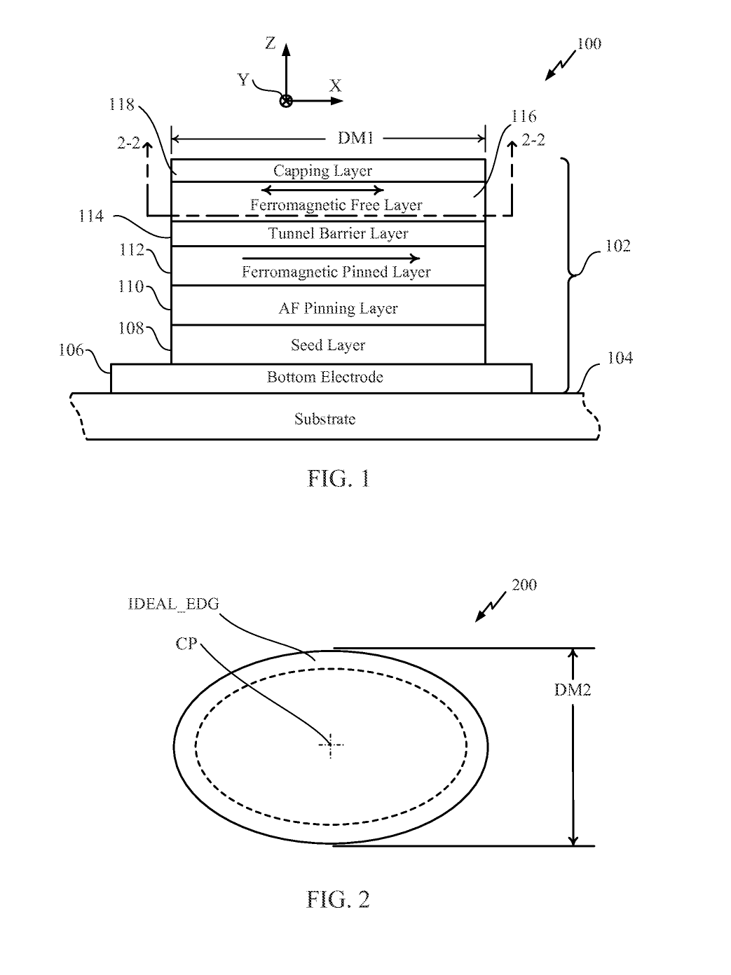

FIG. 2 is a planar view, from the FIG. 1 projection 2-2, of one hypothetical ideal structure 200 of the ferromagnetic free layer 116. It will be understood that the described hypothetical ideal structure 200 of the ferromagnetic free layer 116 may also characterize a hypothetical ideal structure (not explicitly shown) of the ferromagnetic pinned layer 112. The hypothetical ideal structure 200 has a peripheral region, artificially demarcated by a superposed diagram as IDEAL_EDG, having an “ideal” chemical/ferromagnetic structure. For purposes of this description, “ideal” chemical/ferromagnetic structure means the chemical composition and its ferromagnetic properties of the IDEAL_EDG region are the same as the remaining regions of the hypothetical ideal structure 200, i.e., the region encircled and bounded by IDEAL_EDG. For convenience in referring to FIG. 2, the region of the hypothetical ideal structure 200 of the ferromagnetic layer inside the IDEAL_EDG will be termed the “main region.”

Referring still to FIG. 2, the IDEAL_EDG is assumed to result from hypothetical removal of material from a multi-layer MTJ starting structure to obtain the MTJ pillar 102 as a remaining structure—without application of energy and without effecting any chemical reaction. The IDEAL_EDG is therefore not a delineation of any structural changes. On the contrary, as previously described the hypothetical ideal structure 200 is assumed to have uniform chemical make-up and ferromagnetic properties. The IDEAL_EDG is only a reference location, where “location” is defined by radial distance inward (toward the center CP) from the extreme edge EDG, for comparison to structure at similarly located regions in actually fabricated examples of ferromagnetic layers in structures such as the MTJ pillar 102, as described in greater detail at later sections.

As previously described in this disclosure, the IDEAL_EDG of FIG. 2 assumes hypothetical removal of material from a multi-layer MTJ starting structure to obtain the MTJ pillar 102 as a remaining structure—without application of energy and without effecting any chemical reaction. However, known etching techniques for removing material from a multi-layer MTJ starting structure, to obtain the MTJ pillar 102 as a remaining structure, applies energy and, therefore, can effect undesired chemical reactions, i.e., chemical damage. The chemical reactions may include one or more of oxidation, nitridation, or fluorination at the periphery (or a peripheral edge region) of layers forming the MTJ pillar 102, for example at the periphery of the ferromagnetic free layer 116. In addition, transition processes going to a next process step, and CVD (chemical vapor deposition) following the etching process, can create chemical damage to the peripheral of ferromagnetic layers.

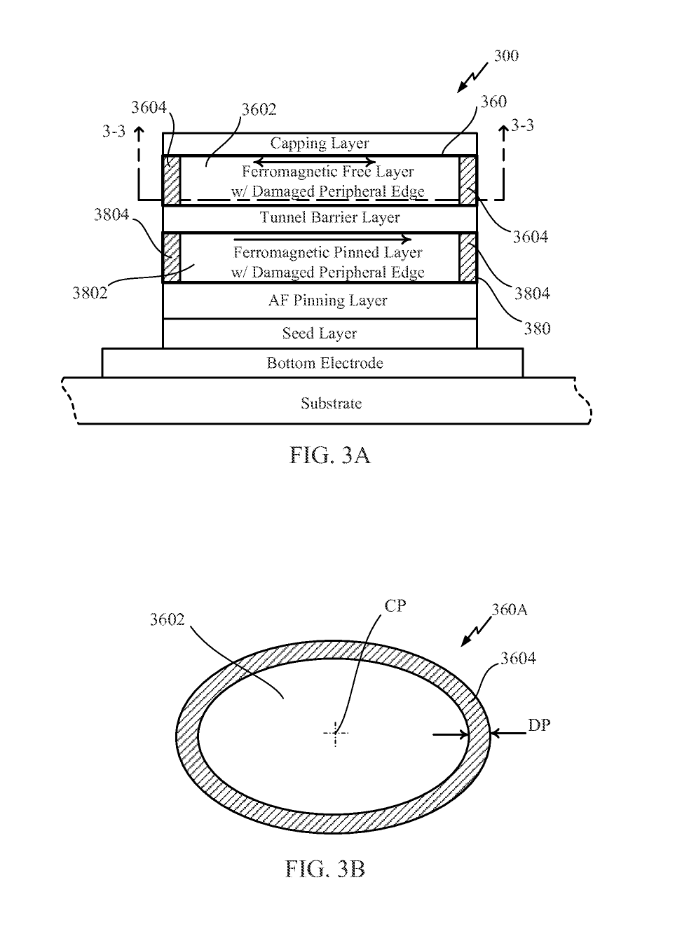

FIG. 3A shows, by diagram superposed on the FIG. 1 cutaway front projection view showing a cross-section of an MTJ pillar structure 300 that is arranged substantially the same as the multi-layer MTJ pillar 102, but having a chemically damaged peripheral edge ferromagnetic (“damaged PEFM”) free layer 360 in place of the FIG. 1 ferromagnetic free layer 116. It will be understood that the term “damaged PEFM” is simply an abbreviation for “chemically damaged peripheral edge ferromagnetic” and carries no additional meaning. The MTJ pillar structure 300 also shows a damaged PEFM pinned layer 380 in place of the FIG. 1 ferromagnetic pinned layer 112. It will be understood, though, that exemplary embodiments may be practiced with any one of, or both of, the damaged PEFM free layer 360 and the damaged PEFM pinned layer 380.

FIG. 3B shows a slice 360A of the damaged PEFM free layer 360, with a superposed diagram showing an example “main” or “central” region 3602, surrounded by the example chemically damaged peripheral region 3604 viewed from the FIG. 3A projection 3-3.

The chemically damaged peripheral region 3604 represents one general distribution of chemical damage that can arise from conventional etching techniques and related processing, e.g., chemical vapor deposition (CVD). The damaged PEFM pinned layer 380 (shown only in FIG. 3A) likewise comprises an undamaged “main” or “central” region 3802 and a chemically damaged peripheral region 3804, representing one general distribution of the above-described chemical damage that can arise from conventional etching techniques and related processing.

For brevity, various examples are described in relation to only the damaged PEFM free layer 360. It will be understood, though, that except where explicitly stated otherwise or where made clear from the context, the examples and the various aspects may be practiced in relation to the damaged PEFM pinned layer 380, or in relation to both the damaged PEFM free layer 360 and the damaged PEFM pinned layer 380.

Referring to FIGS. 3A and 3B, the chemically damaged peripheral region 3604 of the damaged PEFM free layer 360 can represent oxidation, nitridation or both, of the material forming the layer (not explicitly shown) of the MTJ multi-layer starting structure from which the damaged PEFM free layer 360 was etched. The oxidation, nitridation, or both, can arise from, for example, nitrogen or oxygen, or both, introduced during the etching processes. The specific chemical make-up of the oxidation, nitridation, or both that formed the chemically damaged peripheral region 3604 depends, at least in part, on the chemical make-up of the MTJ multi-layer starting structure from which the damaged PEFM free layer 360 was formed.

For example, in an aspect the damaged PEFM free layer 360 may be etched from a layer of a soft ferromagnetic material, for example, iron (Fe). Nitridation of an Fe ferromagnetic can produce hard magnetic materials, for example FeN. A hard magnetic FeN composition of the chemically damaged peripheral region 3604 may have untoward effects in the performance characteristics of the damaged PEFM free layer 360 when the fabrication is complete and it is part of an operative MTJ device. Example of untoward effects can be, for example, large magnetic saturation (Ms), large offset magnetic field (Hoff), lower exchange constant, reduced tunnel magnetoresistance (TMR), and/or degradation of the R-H loop, alone or in combination.

Continuing to refer to FIGS. 3A-3B, the chemically damaged peripheral region 3604 can have an outer extremum at, or substantially coincident with, the outer edge (shown but not separately labeled), and can extend to an average depth DP measured in a radial direction to a geometric center CP. For purposes of example, the damaged PEFM free layer 360 will be assumed to have an elliptical shape having a major and minor diameter (shown but not labeled on FIG. 3B) that may be the same as “DM1” and DM2” labeled on FIGS. 1 and 2. It will be understood that the FIG. 3B graphic representation of the ratio of the average depth DP relative to the diameter (e.g., DM1, DM2, or an average of DM1, DM2) is for visibility in the figures and is not intended to represent a numerical value of the ratio of DP to the diameter.

It is notable that in conventional fabrication of MTJ devices, after etching to form pillars such as the FIG. 1 MTJ pillar 102, one or more layers can be applied. It is further notable that in instances in conventional fabrication in which the etching forms damage regions, as shown by the FIG. 3A-3B chemically damaged peripheral region 3604, that the one or more layers may be applied on such damaged peripheral regions. Such layers can be referred to in the conventional MTJ fabrication art as “protective layers.”

As will be described in greater detail at later sections, according to one embodiment all, or at least a selected, sufficient percentage of the chemically damaged peripheral region 3604, can be transformed to a “chemically modified peripheral portion” (not shown in FIGS. 3A and 3B) that is fully ferromagnetic dead. Together with related novel structure(s), the chemically modified peripheral portion can provide, among other benefits described in greater detail at later sections, significant reduction and/or elimination of the above-described degradation in magnetic properties arising from chemical edge damage that can occur in conventional MTJ magnetic layer techniques.

In an aspect, transformation of the chemically damaged peripheral region 3604 to a magnetic dead chemically modified peripheral portion can include an oxidation process. In a related aspect, transformation of the chemically damaged peripheral region 3604 to a magnetic dead chemically modified peripheral portion can include a nitridation process. In a further aspect, transformation of the chemically damaged peripheral region 3604 to a magnetic dead chemically modified peripheral portion can include a fluorination process. In another aspect, transformation of the chemically damaged peripheral region 3604 to a magnetic dead chemically modified peripheral portion can include a combination of any two or more from among a nitridation process, an oxidation process and/or a fluorination process.

Various exemplary embodiments apply, as described in greater at later sections, one or more of a nitridation process, oxidation process and fluorination process, in aspects configured to utilize and exploit such processes acting significantly faster on the damaged crystalline structure of the chemically damaged peripheral region of an in-process ferromagnetic layer, than on the not damaged crystalline structure of the remaining, i.e., central region.

Further to this aspect, the nitridation process, the oxidation process, the fluorination process, or any combination of these, can continue until an acceptable percentage of the chemically damaged peripheral region of the in-process or intermediate step ferromagnetic layer is oxidized, nitrided or fluorinated to form the chemically modified peripheral region. It will be understood by persons or ordinary skill in the art from this disclosure that the nitridation process, the oxidation process or the fluorination process, or any combination among these processes can terminate before causing unacceptable oxidizing or nitriding of the undamaged central region of the in-process or intermediate step ferromagnetic layer. In other words, in an aspect, the nitridation process, the oxidation process or the fluorination process, or any combination among these processes may continue with increasing depth into the chemically damaged peripheral region and, preferably, terminate at or just prior to reaching the depth of that damaged region. As will be appreciated, this processing may produce a ferromagnetic layer having a constant, good ferromagnetic property along a radial line from its center, followed by a sharp gradient transition to a ferromagnetic dead property.

In an aspect, the intermediate step or in-process ferromagnetic layer can comprise a ferromagnetic element, for example cobalt (Co), iron (Fe), nickel (Ni) and/or boron (Bo), or compounds of ferromagnetic elements, for example, CoFeB, CoFe, NiFe, or any combination or sub-combination of these. According to this aspect, the chemically modified peripheral region can include, further to the oxidation process, one or more from among FeOx, CoOx, CoFeOx, NiFeOx, and/or BOx. Likewise, in an aspect further to the nitridation process, the peripheral chemically modified portion can include one or more from among FeNx, CoNx, CoFeNx, NiFeNx and/or BNx. In an aspect further to the fluorination process, the chemically modified peripheral region can include one or more of CoFx, FeFx, NiFeFx, BFx and/or CoFeFx. Aspects employing combinations of, or sub-combinations of two from among oxidation, nitridation and fluorination can include combinations of the above-identified chemical compounds.

In another aspect, after transformation of the chemically damaged peripheral region 3604 to a chemically modified peripheral portion, by oxidation, nitridation, and/or fluorination, or any combination of the same in accordance with various exemplary embodiments, a trim or ion milling process can be performed to remove all, or most of the chemically modified peripheral portion.

In another aspect, either in combination with the aspect of removing all, or most of the chemically modified peripheral portion, or without performing such removal, a protective layer can be applied. In an aspect, the protective layer can be an oxide layer or a nitride layer, for example, AlOx.

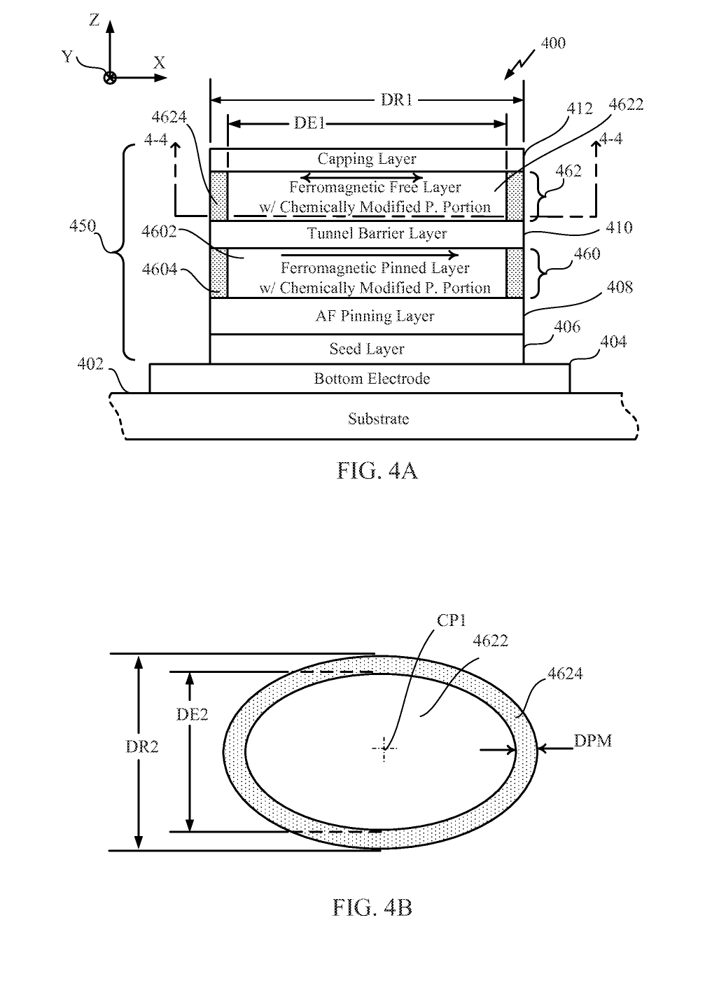

FIG. 4A is a cross-sectional view, on a projection plane X-Z normal to the extending X-Y plane of constituent layers, showing aspects of one example chemically modified edge (“CME”) multi-layer MTJ device 400 structured according to, and formed in accordance with one or more exemplary embodiments. It will be understood that the term “CME” is simply an abbreviation for “chemically modified edge” and carries no additional meaning. FIG. 4B is a view from FIG. 4A projection 4-4, showing one CME ferromagnetic layer of the FIG. 4A CME multi-layer MTJ device 400 structured according to, and formed in accordance with one exemplary embodiment.

The FIG. 4A CME multi-layer MTJ device 400 is shown in simplified form omitting, for example, read/write access and other circuitry for which description is not necessary for persons of ordinary skill in the art, having view of this disclosure, to understand the inventive concepts and practice according to one or more of the exemplary embodiments. It will be understood that “device,” as used in the term “CME multi-layer MTJ device” 400 or “chemically modified edge multi-layer MTJ device” 400, is not intended to limit practices according to any of the exemplary embodiments to fully fabricated devices. For example, the CME multi-layer MTJ device 400 can be an “in-process” structure, i.e., portions (not separately labeled) of its depicted structure may be removed or may be modified by subsequent processing, in accordance with conventional MTJ fabrication techniques.

The FIG. 4A-4B CME multi-layer MTJ device 400, for convenience, has the general stacking configuration of the FIG. 1 multi-layer MTJ device 100. It will be understood that this example is used to assist in focusing on novel aspects, without requiring introduction and description of additional structures not particular to the exemplary embodiments. As will be readily appreciated by persons of ordinary skill in the art, upon reading this disclosure, practices in accordance with various exemplary embodiments are not limited to structures adopting the general stacking configuration of the FIG. 1 multi-layer MTJ device 100.

Referring to FIG. 4A, the CME multi-layer MTJ device 400 can include an MTJ substrate 402 (hereinafter “substrate” 402), and a bottom electrode 404 disposed on the substrate 402. The substrate 402 and bottom electrode 404 can be structured, and formed in accordance with conventional MTJ techniques. Above the substrate 402, on an upper surface (shown in cross-section, but not separately labeled) of the bottom electrode 404, may be a multi-layer pillar structure 450 (hereinafter “MTJ pillar” 450). The MTJ pillar 450 may comprise, in bottom-to-top order (i.e., the arrow direction of the “Z” axis), a seed layer 406, an AF pinning layer 408, chemically modified edge (“CME”) ferromagnetic pinned layer 460, a tunnel barrier layer 410, CME ferromagnetic free layer 462 and capping layer 412. In an aspect, the CME ferromagnetic pinned layer 460 can comprise a main region 4602 and a chemically modified peripheral region 4604. In a further aspect, the CME ferromagnetic free layer 462 can comprise a main region 4622 and a chemically modified peripheral portion 4624. In one aspect, main region 4602 of the CME ferromagnetic pinned layer 460 can comprise ferromagnetic materials such as CoFeB or CoFe, or both. In one related aspect, chemically modified peripheral region 4604 of the CME ferromagnetic pinned layer 460 can comprise FeOx, CoOx, CoFeOx, BOx, FeNx, CoNx, CoFeNx, BNx, FeFx, CoFx, CoFeFx, and/or BFx any combination or sub-combination of any of these chemical compounds.

Continuing to refer to FIG. 4A, in one aspect, main region 4622 of the CME ferromagnetic free layer 462 can comprise any one of, or any combination or sub-combination of CoFeB, CoFe and NiFe. In one related aspect, chemically modified peripheral region 4624 of the CME ferromagnetic free layer 462 can comprise FeOx, CoOx, CoFeOx, BOx, FeNx, CoNx, CoFeNx, BNx, FeFx, CoFx, CoFeFx, and/or BFx, or any combination or sub-combination of any of these chemical compounds.

It will be understood that the FIGS. 4A and 4B CME multi-layer MTJ device 400 having both CME ferromagnetic free layer 462 and CME ferromagnetic pinned layer 460 is not intended to limit the scope of any of the embodiments to this combination. Instead, if desired, practices according to one or more of the exemplary embodiments may include the CME ferromagnetic free layer 462 but, instead of forming the CME ferromagnetic pinned layer 460, may retain a ferromagnetic pinned layer (not shown in FIGS. 4A-4B) having a chemically damaged peripheral region. Similarly, practices according to one or more of the exemplary embodiments can include the CME ferromagnetic pinned layer 460 but, instead of the CME ferromagnetic free layer 462, may retain a ferromagnetic free layer (not shown in FIGS. 4A-4B) having a chemically damaged peripheral region.

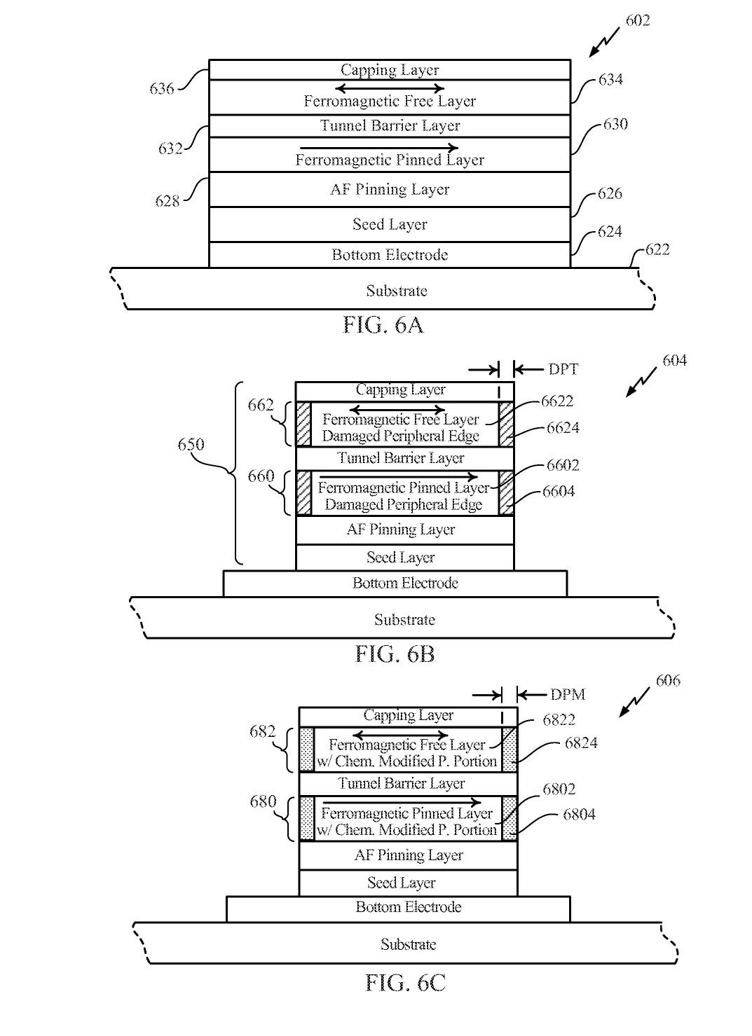

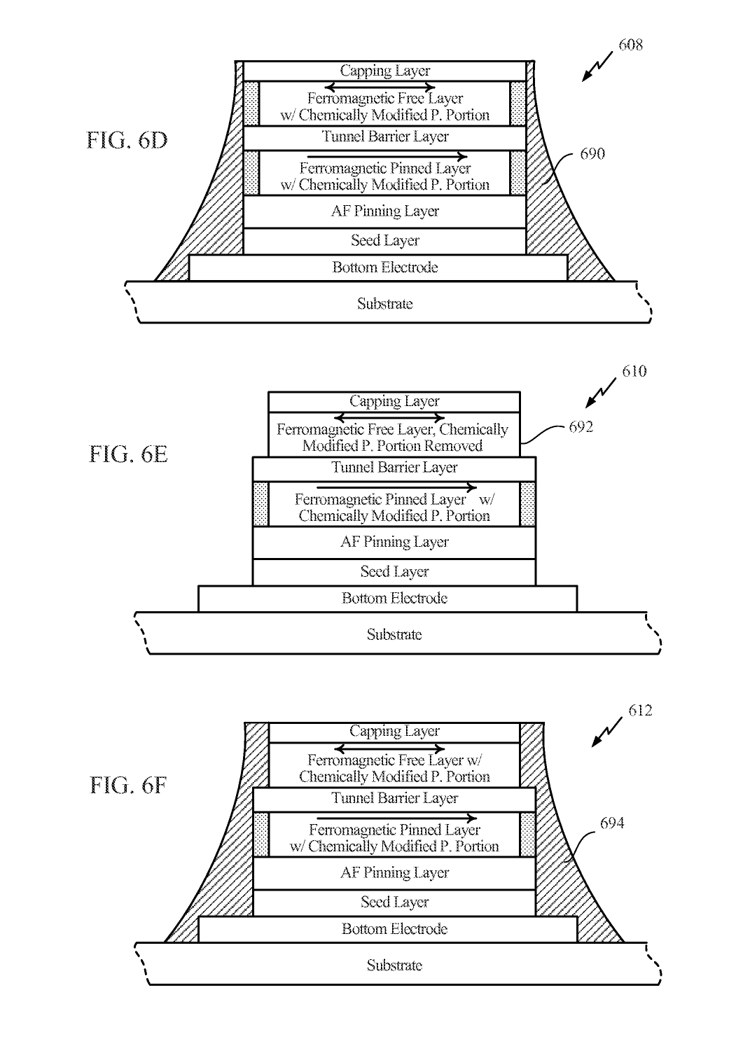

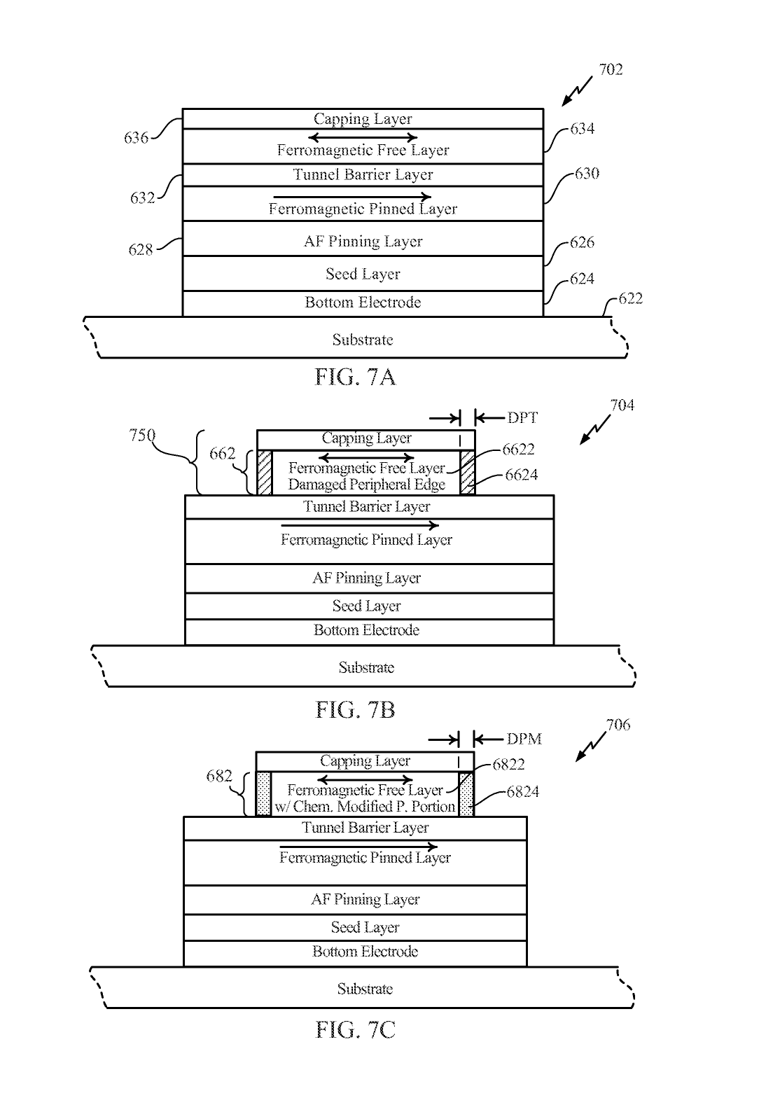

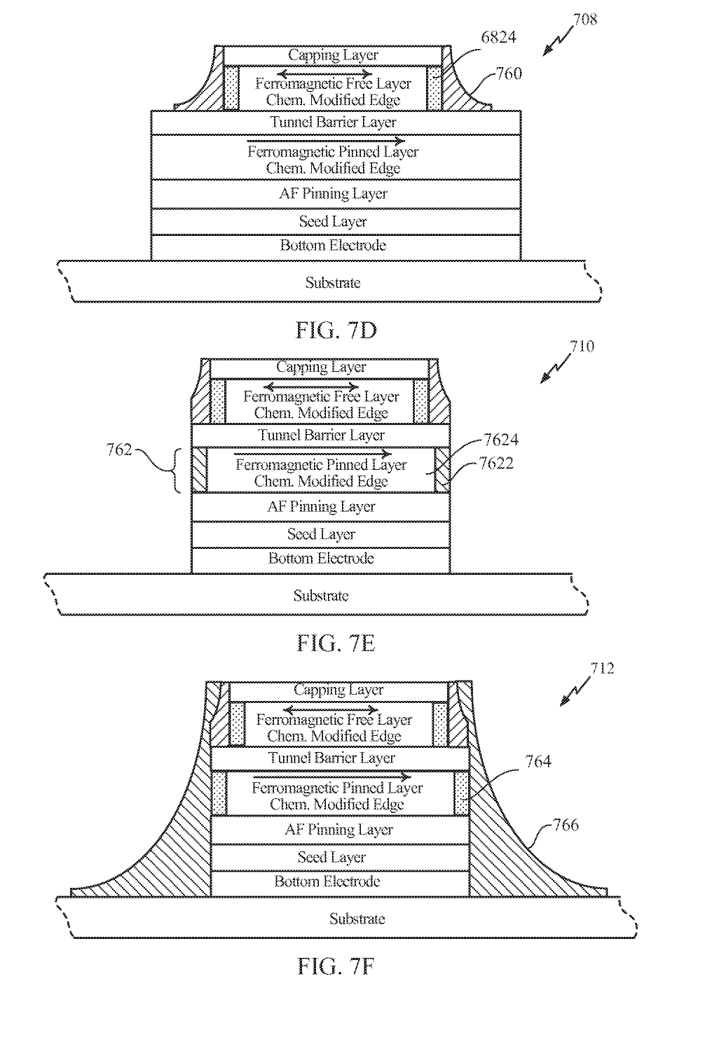

Snapshot sequences of example in-process structures, illustrating results of example processes in practices of one or more exemplary embodiments in forming structures, such as the FIG. 4A CME multi-layer MTJ device 400, will be described in greater detail in reference to FIGS. 6A-6F. Example processes in practicing one or more exemplary embodiments that form structures such as the FIG. 4A CME multi-layer MTJ device 400, will be described in greater detail in reference to FIG. 7.

Referring to FIG. 4B, in an aspect, one exemplary embodiment can include selecting a total surface area for the CME ferromagnetic free layer 462. In this aspect, “total surface area” means an area corresponding to the overall widths DR1 and DR2 of the example elliptical shape of the MTJ pillar 450. It will be understood that the total surface area is larger than a target or given effective MTJ area. The target or given effective MTJ area (hereinafter collectively referenced as “target effective MTJ area”) can be a given area dimension, i.e., defined in units of area. The target effective MTJ area may be further defined according to widths and lengths, e.g., the DE1 and DE2 of the main region 4622 of the CME ferromagnetic free layer 462. As readily appreciated by persons of ordinary skill in the art, the difference between the total surface area and the target effective MTJ area (i.e., the difference between DR1 and DE1, and the difference between DR2 and DE2) corresponds to the depth DPM of the chemically modified peripheral portion 4624. In an aspect, the depth DPM can be approximately the same as the depth (not shown in FIGS. 4A and 4B) of the chemically damaged peripheral region (not shown in FIGS. 4A and 4B) of the above-described precursor to the CME ferromagnetic free layer 462. Therefore, a target effective MTJ area may be identified or obtained according to this aspect by straightforward estimation, or empirical observation, of the depth of the chemically damaged peripheral region. Ferromagnetic layers may then be fabricated, in accordance with one or more exemplary embodiments, with an actual area based on adding that calculated or observed depth to the target value.

Referring still to FIG. 4B, it will be understood that an aspect can include selecting a total surface area for the CME ferromagnetic pinned layer 460, for example in a manner similar to the above-described aspect, based on the target effective area and the calculated or observed depth of the damaged peripheral region.

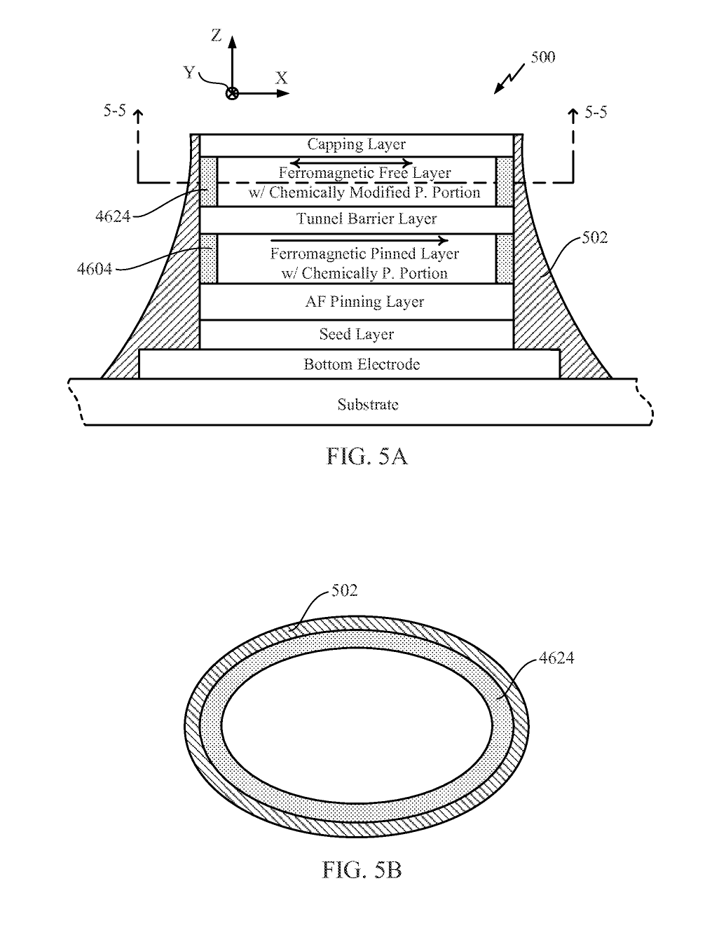

FIG. 5A is a cross-sectional view, on an X-Z projection plane normal to the extending X-Y plane of the constituent layers, showing aspects of one example chemically modified edge (“CME”) multi-layer MTJ device 500 structured according to, and formed in accordance with another exemplary embodiment. In an aspect, the CME multi-layer MTJ device 500 can include the CME multi-layer MTJ device 400, further combined with a protective layer 502. Further to the aspect, the protective layer 502 may be formed over the chemically modified peripheral portion 4604 of the CME ferromagnetic pinned layer 460, and over the chemically modified peripheral portion 4624 of the CME ferromagnetic free layer 462. The protective layer 502 may be formed of, for example, AlOx.

Various benefits of the protective layer 502 may include, for example, a protection against unwanted migration or deepening of the chemically modified peripheral portion 4624 and/or 4604. Other benefits of the protective layer 502 may be a protection chemical damage to the chemically modified peripheral portion 4624 and/or 4604 that may re-insert unwanted weak ferromagnetic effects. In an aspect, the protective layer 502 may be formed immediately after the transformation processed forming the chemically modified peripheral portion 4624 and 4604, respectively, of the CME ferromagnetic free layer 462 and the CME ferromagnetic pinned layer 460.

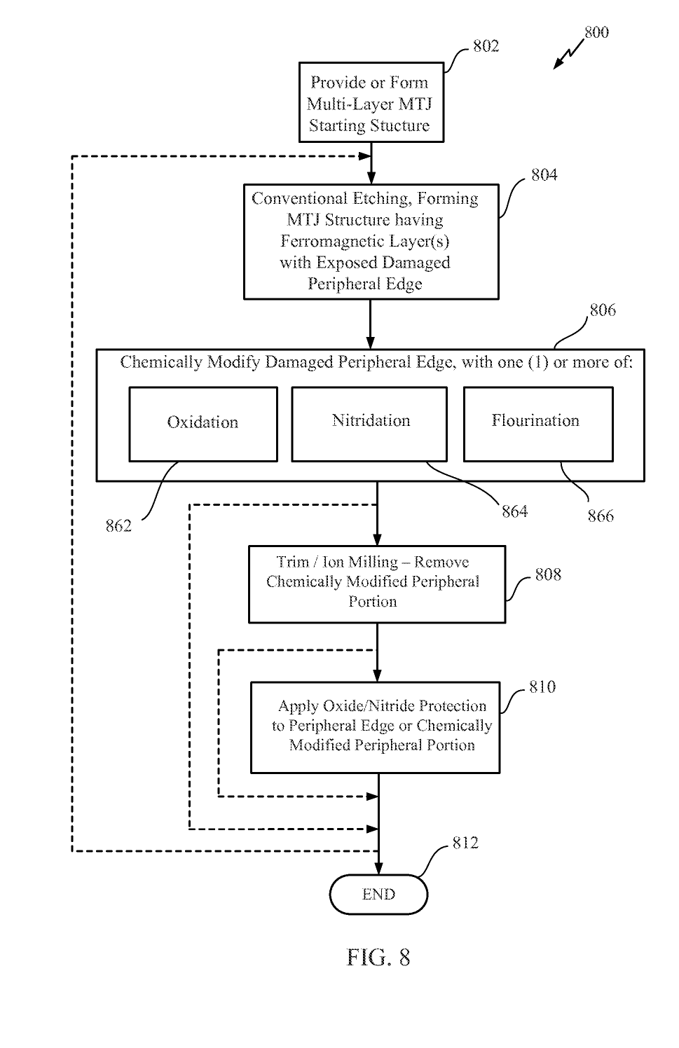

FIGS. 6A-6C show one example sequence of structural formations that may be intermediate structures formed in a process according to aspects of one or more exemplary embodiments, examples of which are described in greater detail in reference to FIG. 8. FIG. 6D shows one example further sequence in accordance with one aspect, which may be combined with the example sequence of FIGS. 6A-6C. FIG. 6E shows one example of another further sequence, in accordance with one aspect, that may be combined with the example sequence of FIGS. 6A-6C. FIG. 6F shows one example of still another further sequence, in accordance with one aspect, that may be combined with the example combination sequence of FIGS. 6A-6C and 6E.

Referring to FIG. 6A, an example MTJ multi-layer starting structure 602 can be formed or provided, and may have, listed in their depicted stacking order beginning with MTJ substrate 622 (hereinafter “substrate” 622), bottom electrode 624, seed layer 626. AF pinning layer 628, ferromagnetic pinned layer 630, tunnel barrier layer 632, ferromagnetic free layer 634, and capping layer 636. In an aspect, the ferromagnetic free layer 634 can include CoFeB, NiFe, or CoFe, or any combination or sub-combination of the same. In another aspect, the ferromagnetic pinned layer 630 can include CoFeB, CoFe, or both. With respect to materials forming the MTJ substrate 622, bottom electrode 624, seed layer 626, AF pinning layer 628, tunnel barrier layer 632, and capping layer 636 these can be according to conventional MTJ design techniques and, therefore, further detailed description is omitted. With respect to methods for forming the MTJ substrate 622, bottom electrode 624, seed layer 626, AF pinning layer 628, ferromagnetic pinned layer 630, tunnel barrier layer 632, ferromagnetic free layer 634, and capping layer 636, these can be according to conventional MTJ fabrication techniques and, therefore, further detailed description is omitted.

Referring still to FIG. 6A, in an example process according to one exemplary embodiment, conventional etching can be performed on the FIG. 6A MTJ multi-layer starting structure 602, for example down to the bottom electrode layer 624 to form the FIG. 6B in-process structure 604 having in-process MTJ pillar 650. In an aspect, conventional etching can be used to form the in-process MTJ pillar 650, in a manner such that the in-process MTJ pillar 650 includes chemically damaged peripheral edge ferromagnetic (“damaged PEFM”) pinned layer 660 and damaged PEFM free layer 662. The damaged PEFM pinned layer 660 may be alternatively referred to as “in-process damaged PEFM pinned layer” 660, and the damaged PEFM free layer 662 may be alternatively referred to as the “in-process damaged PEFM free layer” 662. In a related aspect, in-process damaged PEFM free layer 662 includes a chemically damaged peripheral region 6624 and a main region 6622. As previously discussed in this disclosure, the chemically damaged peripheral regions 6604 and 6624 may become weak ferromagnetic, which can have unwanted effects on device performance.

Referring to FIG. 6B, the depth DPT of the chemically damaged peripheral region 6624, measured in an inward radial direction comparable to the direction of the FIG. 3B depth DP, can be readily adjusted by persons of ordinary skill in the art, using conventional etching adjustment techniques. In an aspect it can be assumed that the depth (shown but not separately labeled) of the chemically damaged peripheral region 6604 of the damaged PEFM pinned layer 660 can be the same, or substantially the same as DPT.

As previously described in reference to FIGS. 4A-4B, various exemplary embodiments can include selecting, in reference to FIG. 6B, the overall diameter (shown as the horizontal width, but not separately labeled) of the in-process MTJ pillar 650 such that the diameter of the main region 6622 provides the damaged PEFM free layer 662 with a desired effective MTJ area. The desired effective MTJ area may also be referenced as the “target MTJ area.” As will be readily appreciated by persons of ordinary skill having view of the present disclosure, the depth DPT can be adjusted in view of this aspect.

Referring to FIG. 6B, the chemically damaged peripheral regions 6624 and 6604 of the damaged PEFM free layer 662 and damaged PEFM pinned layer 660 can still have ferromagnetic property, albeit weak, i.e., significantly degraded in comparison to the ferromagnetic property of the main regions 6622 and 6602. A reason for the remaining weak ferromagnetic property of the chemically damaged peripheral regions 6624 and 6604 is that although the damage resulted from O, N and/or F diffusing into these regions, the diffusion was insufficient to cause total, or sufficiently total, oxidation, nitridation, or fluorination. The result is that the chemically damaged peripheral regions 6624 and 6604 have significantly degraded ferromagnetic properties, for example significantly decreased ferromagnetic exchange coupling. This, in turn, can result in significantly degraded MTJ switching properties in the final device. Processes and apparatuses in accordance with various exemplary embodiments provide, among other features and benefits, significant reduction or elimination of these degrading effects by performing transformation processes that transform all, or an acceptable percentage of, the respective chemically damaged peripheral region 6604 and/or the chemically damaged peripheral region 6624 to a chemical composition that is ferromagnetic dead.

FIG. 6C shows a device 606 that can be provided by a transformation process, in accordance with one or more exemplary embodiments, on structures such as the FIG. 6B in-process structure 604. The transformation may include oxidation, nitridation, or fluorination, or any combination or sub-combination of the same. In an aspect, the transformation process may convert or transform substantially all of the respective chemically damaged peripheral region 6604 of the damaged PEFM pinned layer 660 to a ferromagnetic dead chemically modified peripheral portion 6804. The ferromagnetic dead chemically modified peripheral portion 6804 surrounds a main ferromagnetic region 6802. In an aspect, the transforming may be performed such that little, if any, remaining or residual chemically damaged region exists between the chemically modified peripheral portion 6804 and the main ferromagnetic region 6802. In an aspect chemical composition of the chemically modified peripheral portion 6804 can include, for example. FeOx, CoOx, CoFeOx, BOx, FeNx, CoNx, CoFeNx, BNx, FeFx, and/or CoFx, or any combination or sub-combination of these chemical compounds.

Referring still to FIG. 6C, in accordance with one or exemplary embodiments, the transformation process can include an oxidation process. This can provide the chemically modified peripheral portion 6804 with a chemical composition including one or more of FeOx, CoOx, CoFeOx, and/or Box, or any combination or sub-combination of the same. In another aspect, the transformation process can include a nitridation process, providing the chemically modified peripheral portion 6804 with a chemical composition having one of, or a combination of one or of, FeNx. CoNx, CoFeNx and/or BNx. In a further aspect, the transformation process can include a fluorination process, providing the chemically modified peripheral portion 6804 with a chemical composition having one or more from among FeFx and/or CoFx. In another aspect, transformation of the chemically damaged peripheral region 6604 to the magnetic dead chemically modified peripheral portion 6804 can include a combination of any two or more from among a nitridation process, an oxidation process and/or a fluorination process. This, in turn, can provide the chemically modified peripheral portion 6804 with a chemical composition having various combinations and sub-combinations of the above-described chemical compositions provided by any of the processes operating alone.

Referring to FIG. 6C, the device 606 shows, in accordance with an aspect, the transformation adjusted and applied such that depth DPM of the chemically modified peripheral portion 6804 is substantially the same as the FIG. 6B depth DPT of the chemically damaged peripheral region 6624. In aspects of one or more exemplary embodiments, oxidation, nitridation and/or fluorination processes are configured and applied to utilize aspects of acting more rapidly on the chemically damaged peripheral region 6624 than on the main region 6622 (which is undamaged). It will be appreciated that these aspects can provide benefits, for example, easier setting of process parameters, e.g., time and environment, for the oxidation, nitridation and/or fluorination. As one example, oxidation, nitridation and/or fluorination parameters may be more readily set that provide acceptable transformation of the chemically damaged peripheral region 6624, without unacceptable migration of the oxidation, nitridation and/or fluorination into the FIG. 6B main region 6622.

The FIG. 6C device 606 reflects transformations, in accordance with one or more exemplary embodiments, of both the chemically damaged peripheral region 6604 of the damaged PEFM pinned layer 660, and the chemically damaged peripheral region 6624 of the damaged PEFM free layer 662. The transforming forms, respectively, the CME ferromagnetic pinned layer 680 and the CME ferromagnetic free layer 682. The CME ferromagnetic pinned layer 680 results from transforming the chemically damaged peripheral region 6604 of the damaged PEFM pinned layer 660 into the chemically modified peripheral region 6804. The CME ferromagnetic free layer 682 results from transforming the chemically damaged peripheral region 6624 of the damaged PEFM free layer 662 into the chemically modified peripheral region 6824. This is one aspect, and is not intended to limit the scope of any of the exemplary embodiments. For example, by varying one or more of the etching that formed the in-process MTJ pillar 650, the transformation process can be selective to one of the damaged PEFM pinned layer 660 and the damaged PEFM free layer 662. One example two-step etching and repair process in accordance with one or more exemplary embodiments is described later in greater detail, for example in reference to FIGS. 7A-7F.

Referring to FIG. 6C, device 606 can, in an aspect, be a completed device according to can reflect completed processes according to one or more exemplary embodiments. In another aspect, various exemplary embodiments can include forming a protective layer on, for example, one or more of the chemically modified peripheral portion 6804 of the CME ferromagnetic pinned layer 680, and the chemically modified peripheral portion 6824 of the CME ferromagnetic free layer 68.

FIG. 6D shows a cross-sectional view of one example device 608 in accordance with one or more of these exemplary embodiments. The FIG. 6D device 608 includes the FIG. 6C device 606, with protective layer 690 surrounding the pillar (shown but not separately numbered) having the CME ferromagnetic pinned layer 680 and the CME ferromagnetic free layer 682. The protective layer may be formed, for example, of AlOx. One example benefit of this aspect can be the protective layer 690 protecting the chemically modified peripheral regions 6804 and 6824 from subsequent damage.

Exemplary embodiments shown at FIGS. 6A-6D have been described as maintaining the chemically modified peripheral regions formed by the transformation aspects, e.g., oxidation, nitridation and/or fluorination. In another aspect, exemplary embodiments may include removing all, or a selected portion of the chemically modified peripheral region. The removal may be performed by, for example, trim or ion milling.

FIG. 6E shows one device 610 having example structure in accordance with, and resulting from processes in according with or more exemplary embodiments that include such removal of all, or a selected portion of the chemically modified peripheral region. The FIG. 6E device 610 is shown, for convenience, as produced from subsequent trim or ion milling processes performed on the FIG. 6C device 606. The FIG. 6E device 610 shows the subsequent trim or ion milling having removed the chemically modified peripheral region 6824 of the FIG. 6C CME ferromagnetic free layer 682 to form what is termed a “non-damaged peripheral region” or, for brevity, “non-damaged” ferromagnetic free layer 692. It will be understood that the term “non-damaged” in the term a “non-damaged peripheral” ferromagnetic free layer 692 encompasses structure having a residual, i.e., non-zero actual damage, but that exhibits acceptably low ferromagnetic properties at its outer periphery as compared to the ferromagnetic main region.

Referring to FIG. 6E, the example device 610 shows trimming or ion milling of only the chemically modified peripheral region 6824, while leaving the chemically modified peripheral region 6804 of the CME ferromagnetic pinned payer 680. It will be understood that this is only for purposes of example, and is not intended to limit the scope of practices according to any exemplary embodiment. For example, a further trim or ion milling operation (not shown in the figures) in accordance with one or more exemplary embodiments may remove the chemically modified peripheral region 6804 of the CME ferromagnetic pinned payer 680.

FIG. 6F shows one device 612 having example structure in accordance with, and resulting from processes in according with or more exemplary embodiments. The device 612 includes, in addition to removal of all, or a selected portion of one or more chemically modified peripheral regions, a protective layer 694. The protective layer is formed to cover the peripheral (shown but not separately labeled) of the FIG. 6E non-damaged ferromagnetic free layer 692 and, in a further aspect, the chemically modified peripheral portion 6804 of the CME ferromagnetic pinned layer 680.

FIGS. 7A-7F show example snapshots of structures formed in a two-step etching and repair process in accordance with one or more exemplary embodiments. To assist in focusing on aspects particular to the two-step etching and repair process, example operations and example snapshots of structures are presented and described as a modification of certain operations and certain structures described in reference to FIGS. 6A-6F.

Referring to FIG. 7A, one example process may begin with an MTJ multi-layer starting structure 702 that may be identical to the FIG. 6A MTJ multi-layer starting structure 602 that is previously described. In one example process according to one exemplary embodiment, a first etching, which may be according to conventional etching techniques, can be performed on the FIG. 7A MTJ multi-layer starting structure 702 to form the in-process structure 704 having in-process pillar 750. The in-process pillar 750 may include, as an in-process ferromagnetic layer, the previously described damaged PEFM free layer 662. In an aspect, the damaged PEFM free layer 662 may include the chemically damaged peripheral region 6624 and the main region 6622 which, as previously described, is ferromagnetic. The chemically damaged peripheral region 6624 may have the previously described depth DPT. The overall diameter (shown as the horizontal width, but not separately labeled) of the in-process pillar 750 may, as previously described, provide the main region 6622 with the desired effective, or target MTJ area. The chemically damaged peripheral region 6624 of the damaged PEFM free layer 662 can, as previously described, still have weak ferromagnetic property, i.e., significantly degraded in comparison to the ferromagnetic property of the main regions 6622 and 6602.

FIG. 7C shows a device 706 having the chemically modified edge, or CME ferromagnetic free layer 682, that can be provided from a transformation process, in accordance with one or more exemplary embodiments, on structures such as the FIG. 7B in-process structure 704. The FIG. 7C device 706 with its CME ferromagnetic free layer 682 may be provided by a transforming, employing any one of, or any combination of oxidation, nitridation and/or fluorination. In an aspect, the transforming may be performed (e.g., have time duration) that transforms substantially all of the respective chemically damaged peripheral region of 6624 of the FIG. 7B damaged PEFM free layer 662 to form the FIG. 7C CME ferromagnetic free layer having a chemically modified peripheral region 6824 surrounding a main region 6822. As previously described, the chemically modified peripheral region 6824 can include FeOx, NiFeOx, CoOx, CoFeOx, BOx, FeNx, NiFeOx, CoNx, CoFeNx, BNx, FeFx, NiFeFx, CoFx, CoFeFx and/or BFx, or any combination or sub-combination of these chemical compounds. The chemical composition of the chemically modified peripheral region 6824, in accordance with an aspect, can be ferromagnetic dead.

FIG. 7D shows an in-process device 708 having, in an aspect, a protective layer 760 that may be formed on, e.g., surrounding, surfaces including chemically modified peripheral region 6824 formed as described in reference to FIG. 7C. The protective layer may be formed, for example, of AlOx. Next, as shown at FIG. 7E, another, or second etching may be performed, extending for example down to the substrate 622 to form in-process structure 710. In an aspect, the etching that results in the FIG. 7E in-process structure 710 lowers the floor or base of, i.e., extends the in-process pillar 750 to include a portion of the ferromagnetic pinned layer 630 as another, or second in-process ferromagnetic layer 762.

The second in-process magnetic layer 762 is, in this example, an in-process ferromagnetic pinned layer. The etching, though, can be an example of a second etching forming a second in-process ferromagnetic layer having a second chemically damaged peripheral edge region surrounding a second ferromagnetic main region. In the specific example of the second in-process ferromagnetic layer being the in-process ferromagnetic pinned layer 762, a chemically damaged peripheral edge region 7622 surrounds a ferromagnetic main region 7624.

It may be appreciated, referring to FIGS. 7D and 7E, benefits and features of the protective layer 760 may include, for example, protecting the chemically modified peripheral portion 6824 from damage arising from the etching forming the FIG. 7E in-process structure 710. Similarly, it will be appreciated that the protective layer 760 protected the ferromagnetic main region 6822 from damage.

It will be understood that the depth of the etching shown at FIG. 7E is only for purposes of example. The etching may stop, for example, at the seed layer 626 or, as another example, at the bottom electrode 624. In another alternative, the etching at FIG. 7D may continue to, for example, the seed layer 626, and then a third etching may be performed.

Referring to FIG. 7E, as previously described, the in-process ferromagnetic pinned layer 762 has a chemically damaged peripheral edge region 7622 and a ferromagnetic main region 7624. In an aspect, prior to applying or forming any obstructing structure on the chemically damaged peripheral edge region 7622, a transforming may be performed to transform all, or an acceptable percentage or portion of the chemically damaged peripheral edge region 7622 into a chemically modified peripheral portion. In a further aspect, another protective layer may then be formed over that chemically modified peripheral portion. FIG. 7F shows an example structure 712 having a chemically modified peripheral portion 764, and another protective layer 766 reflecting the above described transforming and formation of another protective layer.

FIG. 8 shows one flow chart diagram of one process 800 further to various aspects of edge-restoration and edge-protection of layers of MTJ devices according to one or more exemplary embodiments.

Referring to FIG. 8, one example operation of or further to process 800 can begin at 802 with providing or forming a multi-layer MTJ starting structure, such as the FIG. 6A MTJ multi-layer starting structure 602, or any other multi-layer starting structure from which MTJ devices can be etched. In an aspect, the MTJ starting structure formed or provided at 802 can include at least one ferromagnetic layer, such as the FIG. 6A starting structure ferromagnetic free layer 634, formed of CoFeB or CoFe.

Referring still to FIG. 8, in one example operation of or further to process 800, after being provided or forming the multi-layer MTJ starting structure at 802, conventional etching of the at least one ferromagnetic layer can be performed at 804 to obtain an intermediate MTJ structure having at least one in-process ferromagnetic layer. The conventional etching at 804 can be configured to form the at least one in-process ferromagnetic layer having a chemically damaged peripheral region, such as the FIG. 6B chemically damaged peripheral region 6624 of the damaged PEFM free layer 662. In an aspect, etching at 804 may form an MTJ pillar having a stack of two or more in-process ferromagnetic layers, such as the FIG. 6B multi-layer in-process MTJ pillar 650. As previously described, the FIG. 6B in-process MTJ pillar 650 includes the in-process damaged PEFM pinned layer 660, tunnel barrier layer 632, and in-process damaged PEFM free layer 662. In another aspect, etching at 804 may be a first etching forming an MTJ pillar such as the FIG. 7B in-process MTJ pillar 750 having, with respect to magnetic tunnel junction layers, only the in-process damaged PEFM free layer 662.

Referring still to FIG. 8, in one example operation of process 800, after etching at 804 to produce one or more in-process damaged edge ferromagnetic layers, a transformation process in accordance with one or more exemplary embodiments may be performed at 806. The transformation operations at 806 may be applied (e.g., have a time duration) to transform, to a magnetic dead chemically modified peripheral portion, all, or a selected, acceptable percentage of, the chemically damaged peripheral region of the in-process ferromagnetic layers formed at 804. In an aspect, the transformation operations at 806 may, as previously described, include oxidation 862, nitridation 864 and/or fluorination 866, or any combination or sub-combination of these.

It will be understood that the transformation operations at 806 should be performed prior to forming obstructing structure on the chemically damaged peripheral regions that are to be transformed. As previously described in this disclosure, in an aspect the transformation operations at 806 may exploit and provide utilization of chemically damaged peripheral regions of ferromagnetic layers undergoing oxidation, nitridation and/or fluorination at rates significantly greater than undamaged portions of the ferromagnetic layers. In accordance with exemplary embodiments, utilization and exploitation can include, for example, setting transformation process parameters, e.g., temperature, oxidation, nitridation and fluorination agents and concentrations, at values at which satisfactory transformation of chemically damaged peripheral regions, i.e., satisfactory depth of the chemically modified peripheral region can be obtained, without unacceptable transformation of undamaged regions.

Referring to FIG. 8, in one example operation of or further to process 800, after the transformation operations at 806 the process may successfully terminate at 812. FIG. 6C shows, by its device 606, one example of such a termination of process after transformation of chemically damaged peripheral regions, to a satisfactory depth, to chemically modified peripheral portions.

In another aspect, in one example operation of process 800, after the transformation operations at 806 the process may go to 808 and, in an example described later in greater detail, perform a trim or ion milling to remove all, or an acceptable portion of all the chemically modified peripheral portions formed at 806.

In another aspect, one example operation of process 800 may, after the transformation operations at 806, go directly to 810 and apply or form a protection layer on the chemically modified peripheral portions formed at 806. Referring to FIG. 6D, device 608 with the protective layer 690 shows one example result of processes contemplated by the forming at 810 of a protection layer. As previously described, the protective layer formed at 810 may be, for example. AlOx. In one aspect, after the forming of the protective layer at 810 the process 800 may successfully terminate at 812. In another aspect, if the etching at 804 was a first (or other intermediate) etching that formed a pillar such as the FIG. 7B in-process pillar 750, not yet having the pinned ferromagnetic layer, then operations of process 800 can return to 804 and perform another etching, to a depth greater than reached at the prior etching. It will be appreciated that the protective layer formed at 810 may protect the chemically modified peripheral portion of the free ferromagnetic layer formed at 806. In an aspect, after performing the another etching the above-described block to obtain an in-process pinned ferromagnetic layer, block 806 may be repeated to repair the chemically damaged peripheral edge region of the in-process pinned ferromagnetic layer. It will also be appreciated that the protective layer formed at 810 may protect the chemically modified peripheral portion of the free ferromagnetic layer formed at 806 from further oxidation, nitridation and/or fluorination during this repair of the chemically damaged peripheral edge region of the in-process pinned ferromagnetic layer.

Referring to FIG. 8, as previously described, in one example operation of process 800, after the transformation operations at 806 the process may go to 808 and perform a trim or ion milling to remove all, or an acceptable portion of all, or selected ones of the chemically modified peripheral portions formed at 806. The FIG. 6E device 610, which is a result of operating on the FIG. 6C device 606 to remove the chemically modified peripheral region 6824 of the CME ferromagnetic free layer 682, shows one example structure that may be formed in accordance with the trim or ion milling at 808.

In one aspect, after performing a trim or ion milling at 808 as described above, operations in the process 800 may terminate at 812. In another aspect, after performing a trim or ion milling at 808 as described above, operations in the process 800 may go to 810 and apply or form a protective coating, as previously described, and then terminate successfully at 812. The FIG. 6F device 612, which is the FIG. 6E device with protective coating 694, shows one example structure that may be formed in accordance with a sequence such as the trim or ion milling at 808 followed by forming a protective layer at 810.

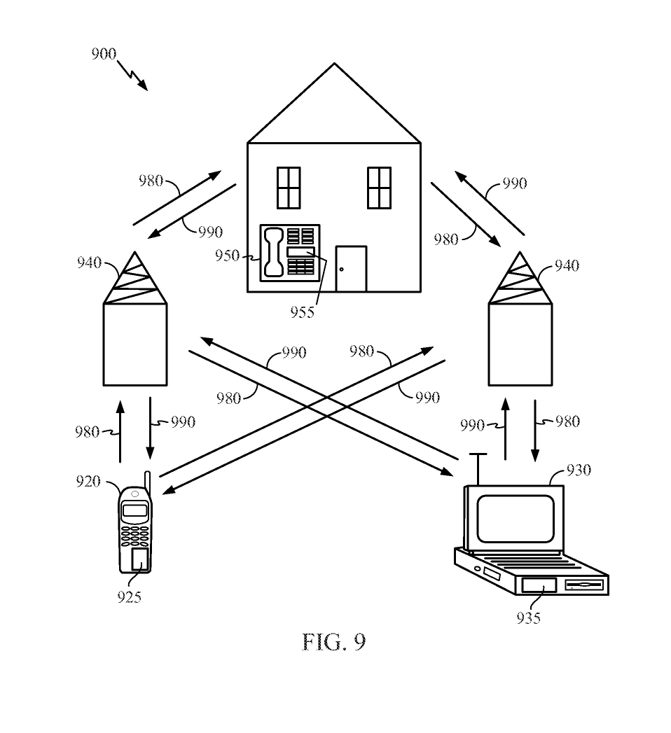

FIG. 9 illustrates an exemplary wireless communication system 900 in which one or more embodiments of the disclosure may be advantageously employed. For purposes of illustration, FIG. 9 shows three remote units 920, 930, and 950 and two base stations 940. It will be recognized that conventional wireless communication systems may have many more remote units and base stations. The remote units 920, 930, and 950 include integrated circuit or other semiconductor devices 925, 935 and 955 (including on-chip voltage regulators, as disclosed herein), which are among embodiments of the disclosure as discussed further below. FIG. 9 shows forward link signals 980 from the base stations 940 and the remote units 920, 930, and 950 and reverse link signals 990 from the remote units 920, 930, and 950 to the base stations 940.

In FIG. 9, the remote unit 920 is shown as a mobile telephone, the remote unit 930 is shown as a portable computer, and the remote unit 950 is shown as a fixed location remote unit in a wireless local loop system. For example, the remote units 920, 930 and 950 may be any one or combination of a mobile phone or communication device, hand-held personal communication system (PCS) unit, portable data unit such as a personal digital assistant or personal data assistant (PDA), navigation device (such as GPS enabled devices), set top box, music player, video player, or other entertainment unit. The remote units 920, 930 and 950 may, in addition, be any fixed location data unit such as meter reading equipment, or any other device that stores or retrieves data or computer instructions, or any combination thereof. It will be understood that although FIG. 9 illustrates remote units 920, 930 and 950, the various exemplary embodiments are not limited to these illustrated example units. Embodiments of the disclosure may be suitably employed in any device that includes active integrated circuitry including memory and on-chip circuitry for test and characterization.

The foregoing disclosed devices and functionalities (such as the devices of FIGS. 5A-5B, sequence of structures shown by FIGS. 6A-6F, methods of FIG. 7, or any combination thereof) may be designed and configured into computer files (e.g., RTL, GDSII, GERBER, etc.) stored on a computer readable tangible medium or other computer readable media. Some or all such files may be provided to fabrication handlers who fabricate devices based on such files. Resulting products include semiconductor wafers that are then cut into semiconductor die and packaged into a semiconductor chip. The semiconductor chips can be employed in electronic devices, such as described hereinabove.

The methods, sequences and/or algorithms described in connection with the embodiments disclosed herein may be embodied directly in hardware, in a software module executed by a processor, or in a combination of the two. A software module may reside in RAM memory, flash memory, ROM memory, EPROM memory, EEPROM memory, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor.

Accordingly, an embodiment of the invention can include a computer readable media, for example a computer readable tangible medium, embodying a method for implementation. Accordingly, the invention is not limited to illustrated examples and any means for performing the functionality described herein are included in embodiments of the invention.

The foregoing disclosed devices and functionalities may be designed and configured into computer files (e.g., RTL, GDSII, GERBER, etc.) stored on computer readable media. Some or all such files may be provided to fabrication handlers who fabricate devices based on such files. Resulting products include semiconductor wafers that are then cut into semiconductor die and packaged into a semiconductor chip. The chips are then employed in devices described above.

While the foregoing disclosure shows illustrative embodiments of the invention, it should be noted that various changes and modifications could be made herein without departing from the scope of the invention as defined by the appended claims. The functions, steps and/or actions of the method claims in accordance with the embodiments of the invention described herein need not be performed in any particular order. Furthermore, although elements of the invention may be described or claimed in the singular, the plural is contemplated unless limitation to the singular is explicitly stated.

What is claimed is:

1. A method for forming a magnetic tunnel junction layer:
forming an in-process ferromagnetic layer having a ferromagnetic main region surrounded by a chemically damaged peripheral region, wherein the chemically damaged peripheral region is weak ferromagnetic; and
transforming at least a portion of the chemically damaged peripheral region to a chemically modified peripheral portion to form the magnetic tunnel junction layer, wherein the chemically modified peripheral portion is non-ferromagnetic.

2. The method of claim 1, wherein transforming at least a portion of the chemically damaged peripheral region to the chemically modified peripheral portion comprises oxidation, nitriding, or fluorination, or any combination thereof.

3. The method of claim 1, further comprising: identifying or providing a target effective area for the magnetic tunnel junction layer, wherein the in-process ferromagnetic layer has an area dimension larger than the target effective area, wherein the transforming includes forming the magnetic tunnel junction layer to have a ferromagnetic main region, and wherein the ferromagnetic main region has an area approximately equal to the target effective area.

4. The method of claim 1, wherein the in-process ferromagnetic layer comprises any among, or any combination or sub-combination of, NiFe, CoFeB, CoFe, or B.

5. The method of claim 1, wherein the chemically modified peripheral portion contains at least one ferromagnetic element.

6. The method of claim 5, wherein the at least one ferromagnetic element is iron, nickel or cobalt.

7. The method of claim 5, wherein the chemically modified peripheral portion comprises any among, or any combination or sub-combination of, FeOx, CoOx, CoFeOx, BOx, FeNx, CoNx, CoFeNx, BNx, FeFx, CoFx, CoFeFx, and/or BFx, or any combination thereof.

8. The method of claim 1, further comprising removing at least a portion of the chemically modified peripheral portion.

9. The method of claim 8, wherein the removing comprises ion milling, etching, or a combination of ion milling and etching.

10. The method of claim 1, further comprising forming a protective layer to surround the chemically modified peripheral portion.

11. The method of claim 10, wherein the protective layer is an oxide layer, a nitride layer, or a combination of an oxide layer and a nitride layer.

12. The method of claim 10, wherein the protective layer comprises AlOx.

13. The method of claim 1, wherein the in-process ferromagnetic layer is an in-process ferromagnetic free layer.

14. The method of claim 1, wherein the in-process ferromagnetic layer is an in-process ferromagnetic pinned layer.

15. The method of claim 1, wherein the in-process ferromagnetic layer is a first in-process ferromagnetic layer having a first in-process area dimension, wherein the chemically damaged peripheral region is a first chemically damaged peripheral region,
wherein the forming an in-process ferromagnetic layer includes forming a pillar having
the first in-process ferromagnetic layer,
a second in-process ferromagnetic layer, and a
tunnel barrier layer between the first in-process ferromagnetic layer and the second in-process ferromagnetic layer,
wherein the second in-process ferromagnetic layer has a second in-process area dimension larger than the first in-process area dimension, and
wherein the second in-process ferromagnetic layer has a second chemically damaged peripheral region.

16. The method of claim 15, wherein the first in-process ferromagnetic layer is an in-process ferromagnetic free layer.

17. The method of claim 16, wherein the second in-process ferromagnetic layer is an in-process ferromagnetic pinned layer.

18. A method for fabricating a magnetic tunnel junction device, comprising:
providing a multi-layer structure including a substrate, a pinned ferromagnetic layer above the substrate, a tunnel barrier layer above the pinned ferromagnetic layer, and a ferromagnetic free layer above the tunnel barrier layer;
etching the multi-layer structure to form a pillar, the pillar including an in-process ferromagnetic layer having a portion of the ferromagnetic free layer, wherein the in-process ferromagnetic layer includes a ferromagnetic main region and a chemically damaged peripheral region surrounding the ferromagnetic main region, and wherein the chemically damaged peripheral region is weak ferromagnetic; and
transforming at least a portion of the chemically damaged peripheral region to a chemically modified peripheral portion, wherein the chemically modified peripheral portion is ferromagnetic dead.

19. The method of claim 18, wherein the method further comprises:
forming a protective layer to surround the chemically modified peripheral portion; and
another etching to further form the pillar to include another in-process ferromagnetic layer, the another in-process ferromagnetic layer having a portion of the pinned ferromagnetic layer.

20. The method of claim 19, wherein the protective layer is an oxide layer, a nitride layer, or a combination of an oxide layer and a nitride layer.

21. The method of claim 19, wherein the another in-process ferromagnetic layer is the ferromagnetic pinned layer that includes another ferromagnetic main region and another chemically damaged peripheral region surrounding the another ferromagnetic main region, wherein the another chemically damaged peripheral region is weak ferromagnetic, wherein the method further comprises:
transforming at least a portion of the another chemically damaged peripheral region to another chemically modified peripheral portion, wherein the another chemically modified peripheral portion is ferromagnetic dead.

22. The method of claim 21, wherein the method further comprises:
forming a protective layer to surround the another chemically modified peripheral portion.

23. The method of claim 18, wherein the ferromagnetic free layer is located at a first depth in the multi-layer structure, wherein the pinned ferromagnetic layer is located at a second depth greater than the first depth, and wherein the etching is a first etching, and wherein the first etching is to a depth greater than the first depth and less than the second depth, and wherein the method further comprises:
forming a protective layer to surround the chemically modified peripheral portion; and
a second etching to a depth greater than the second depth to further form the pillar to include a second in-process ferromagnetic layer, the second in-process ferromagnetic layer having a portion of the pinned ferromagnetic layer.

24. The method of claim 23, wherein the protective layer is an oxide layer, a nitride layer, or a combination of an oxide layer and a nitride layer.

25. The method of claim 23, wherein the second in-process ferromagnetic layer is an in-process pinned ferromagnetic layer having a second ferromagnetic main region and a second chemically damaged peripheral region surrounding the second ferromagnetic main region, wherein the second chemically damaged peripheral region is weak ferromagnetic, wherein the method further comprises:
transforming at least a portion of the second chemically damaged region to a second chemically modified peripheral portion, wherein the second chemically modified peripheral portion is ferromagnetic dead.

26. The method of claim 25, wherein the method further comprises:
forming another protective layer to surround the second chemically modified peripheral portion.

27. A method for forming a magnetic tunnel junction (MTJ) layer, comprising:
step of forming an in-process magnetic layer having an in-process area dimension larger than a target effective MTJ area, wherein the step of forming includes forming a chemically damaged region at a periphery of the in-process magnetic layer; and
step of transforming at least a portion of the chemically damaged region to a chemically modified peripheral portion, wherein the chemically modified peripheral portion is non-ferromagnetic.

28. The method of claim 27, further comprising step forming a protective layer to surround the chemically modified peripheral portion.

29. A method for fabricating a magnetic tunnel junction device, comprising:
step of providing a multi-layer structure including a substrate, a pinned ferromagnetic layer above the substrate, a tunnel barrier layer above the pinned ferromagnetic layer, and a ferromagnetic free layer above the tunnel barrier layer;
step of etching the multi-layer structure to form a pillar, the pillar including an in-process ferromagnetic layer having a portion of the ferromagnetic free layer, wherein the in-process ferromagnetic layer includes a ferromagnetic main region and a chemically damaged peripheral region surrounding the ferromagnetic main region, wherein the chemically damaged peripheral region is weak ferromagnetic; and
step of transforming at least a portion of the chemically damaged peripheral region to a chemically modified peripheral portion, wherein the chemically modified peripheral portion is ferromagnetic dead.

30. The method of claim 29, wherein the method further comprises:
step of forming a protective layer to surround the chemically modified peripheral region; and
step of another etching to further form the pillar to include another in-process ferromagnetic layer, the another in-process ferromagnetic layer having a portion of the pinned ferromagnetic layer.

31. An apparatus for forming a magnetic tunnel junction (MTJ) layer, comprising:
means for forming an in-process ferromagnetic layer having an in-process area dimension larger than a target MTJ area, wherein the forming includes forming a chemically damaged region at a periphery of the in-process ferromagnetic layer; and
means for transforming at least a portion of the chemically damaged region to a chemically modified peripheral portion, wherein the chemically modified peripheral portion is ferromagnetic dead.

32. The apparatus of claim 31, wherein the in-process ferromagnetic layer comprises CoFeB, CoFe or a combination of CoFeB and CoFe.

33. The apparatus of claim 31, further comprising means for protecting the chemically modified peripheral portion against damage from further processing.

34. The apparatus of claim 31, wherein the chemically modified peripheral portion contains at least one ferromagnetic element.

35. The apparatus of claim 34, wherein the means for transforming is configured to form the chemically modified peripheral portion to include any among, or any combination or sub-combination of, FeOx, CoOx, CoFeOx, BOx, FeNx, CoNx, CoFeNx, BNx, FeFx, CoFx, CoFeFx, and/or BFx.

36. An apparatus for fabricating a magnetic tunnel junction (MTJ) device having a ferromagnetic layer with a given area dimension, comprising:
means for forming a pillar including an in-process magnetic layer having an in-process area dimension larger than the given area dimension, wherein the forming includes forming a chemically damaged region at a periphery of the in-process magnetic layer, and
means for transforming at least a portion of the chemically damaged region to a chemically modified peripheral portion, wherein the chemically modified peripheral portion is ferromagnetic dead.

37. A magnetic tunnel junction device, comprising:
a substrate;
a pinned ferromagnetic layer above the substrate;
a tunnel barrier layer above the pinned ferromagnetic layer; and
a ferromagnetic free layer above the tunnel barrier layer,
wherein at least one of the pinned ferromagnetic layer or the ferromagnetic free layer has a ferromagnetic main region surrounded by a chemically modified peripheral region that is ferromagnetic dead.

38. The magnetic tunnel junction device of claim 37, wherein the magnetic tunnel junction device is integrated in at least one semiconductor die.

39. The magnetic tunnel junction device of claim 37, further comprising a device, selected from a group consisting of a set top box, music player, video player, entertainment unit, navigation device, communication device, personal digital assistant (PDA), fixed location data unit, and a computer, into which the magnetic tunnel junction device is integrated.

40. A computer-readable medium comprising instructions, which, when executed by a processor apparatus, cause the processor apparatus to perform operations carrying out a method for forming a magnetic tunnel junction layer, comprising instructions that cause the processor apparatus to:
form an in-process ferromagnetic layer having a ferromagnetic main region surrounded by a chemically damaged peripheral region, wherein the chemically damaged peripheral region is weak ferromagnetic; and
transform at least a portion of the chemically damaged peripheral edge region to a chemically modified peripheral portion to form the magnetic tunnel junction layer, wherein the chemically modified peripheral portion is non-ferromagnetic.

41. A computer-readable medium comprising instructions, which, when executed by a processor apparatus, cause the processor apparatus to perform operations carrying out a method for fabricating a magnetic tunnel junction device, comprising instructions that cause the processor apparatus to:
etch a multi-layer structure having a substrate, a pinned ferromagnetic layer above the substrate, a tunnel barrier layer above the pinned ferromagnetic layer, and a ferromagnetic free layer above the tunnel barrier layer, to form a pillar,
wherein the pillar includes an in-process ferromagnetic layer having a portion of the ferromagnetic free layer, wherein the in-process ferromagnetic layer includes a ferromagnetic main region and a chemically damaged peripheral region surrounding the ferromagnetic main region, wherein the chemically damaged peripheral region is weak ferromagnetic, and
wherein the instructions further comprise instructions that cause the processor apparatus to transform at least a portion of the chemically damaged peripheral region to a chemically modified peripheral portion, wherein the chemically modified peripheral portion is ferromagnetic dead.

42. The computer-readable medium of claim 41, further comprising instructions that cause the processor apparatus to:
form a protective layer to surround the chemically modified peripheral portion; and
perform another etch to further form the pillar to include another in-process ferromagnetic layer, the another in-process ferromagnetic layer having a portion of the pinned ferromagnetic layer.
